(19) United States
(12) Patent Application Publication
(10) Pub. No.: US 2006/0186791 A1
(43) Pub. Date: Aug. 24, 2006

(54) Organic electroluminescent element

(76) Inventors: Osamu Yoshitake, Fukuoka (JP); Hiroshi Miyazaki, Fukuoka (JP); Shinya Saikawa, Niigata (JP); Yu Yamada, Tokyo (JP)

Correspondence Address: BIRCH STEWART KOLASCH & BIRCH, PO BOX 747, FALLS CHURCH, VA, 22040-0747, US

(21) Appl. No.: 10/557,595

(22) PCT Filed: May 25, 2004
(86) PCT No.: PCT/JP04/07444

§ 371 Date: Nov. 22, 2005

(30) Foreign Application Priority Data
May 29, 2003 (JP) 2003-153195

(51) Int. Cl. H01J 1/62

(52) U.S. Cl. 313/503

(57) ABSTRACT

This invention relates to an organic electroluminescent element comprising a substrate, an anode, an organic layer and a cathode placed in layer one upon another; at least one layer in the organic layer is a luminescent layer comprising a host agent and a doping agent and an azole compound having an oxadiazole structure and a triazole structure in its molecule is used in at least one layer in the organic layer. This azole compound is used as a host agent in the luminescent layer and it can also be used in a hole blocking layer or electron transporting layer. This organic EL element is suitable for use in full-color and multicolor panels and shows a higher luminous efficiency and better driving stability than EL elements utilizing the luminescence from the singlet state.

### FIELD OF TECHNOLOGY

This invention relates to an organic electroluminescent element and, more particularly, to a thin film type device which emits light when an electric field is applied to its luminescent layer comprising organic compounds.

### BACKGROUND TECHNOLOGY

In the development of electroluminescent elements utilizing organic materials (hereinafter referred to as organic EL elements), elements devised by optimizing the kind of electrode and providing a hole transporting layer composed of an aromatic diamine and a luminescent layer composed of 8-hydroxyquinoline aluminum complex in the form of thin films between the electrodes for the purpose of improving the efficiency of electric charge injection from the electrode achieved marked improvement in luminous efficiency compared with the conventional elements utilizing single crystals of anthracene and the like (Appl. Phys. Lett., vol. 51, p. 913, 1987) and the ensuing developmental efforts have been directed to practical use of organic EL elements in high-performance flat panels characterized by self-luminescence and high-speed response.

In order to improve further the efficiency of such organic EL elements, the aforementioned basic structure of anode/hole transporting layer/luminescent layer/cathode has been modified by suitably adding a hole injecting layer, an electron injecting layer or an electron transporting layer: for example, anode/hole injecting layer/hole transporting layer/luminescent layer/cathode; anode/hole injecting layer/luminescent layer/electron transporting layer/cathode; and anode/hole injecting layer/luminescent layer/electron transporting layer/electron injecting layer/cathode. The hole transporting layer has a function of transporting holes injected from the hole injecting layer to the luminescent layer while the electron transporting layer has a function of transporting electrons injected from the cathode to the luminescent layer.

Keying to the functions of the aforementioned constituent layers, a large number of organic materials have been under development.

Now, the aforementioned element that is provided with a hole transporting layer composed of an aromatic diamine and a luminescent layer composed of 8-hydroxyquinoline aluminum complex and many other elements have utilized fluorescence. However, an element utilizing phosphorescence, that is, luminescence from the triplet excited state is expected to improve the efficiency three times or so compared with the conventional elements utilizing fluorescence (singlet). To gain this end, an attempt was made to use the derivatives of coumarin and benzophenone in the luminescent layer, but the result was nothing but extremely low luminance. Thereafter, a europium complex was used in an attempt to utilize the triplet state, but a high efficiency was not achieved.

It is reported in Nature, vol. 395, p. 151 (1998) that red luminescence could be obtained at high efficiency by the use of a platinum complex (PtOEP). Following this, an article in Appl. Phys. Lett., vol. 75, p. 4 (1999) reports that doping the luminescent layer with an iridium complex [Ir(Ppy)₃] greatly improves the efficiency of green luminescence. The article also reports that, by optimizing the luminescent layer, these iridium complexes show an extremely high luminous efficiency even when the structure of the element is further simplified.

In rendering organic EL elements applicable to display elements such as flat panel displays, it is necessary to improve the luminous efficiency of the element and, at the same time, to sufficiently secure the driving stability. However, a highly efficient organic EL element using the phosphorescent molecule [Ir(Ppy)3] described in the aforementioned article shows driving stability that is not enough for the practical use at the present time.

The reason for the aforementioned deterioration of driving stability is presumably the deterioration of the thin film shape of the luminescent layer in the element constructed of substrate/anode/hole transporting layer/luminescent layer/hole blocking layer/electron transporting layer/cathode or substrate/anode/hole transporting layer/luminescent layer/electron transporting layer/cathode. This deterioration of the thin film shape probably results from the crystallization (or cohesion) of a thin organic non-crystalline film caused by heat generated during driving of the element and low heat resistance from low glass transition temperature (Tg) of the material.

In the aforementioned article of Appl. Phys. Lett., a carbazole compound (CBP) or a triazole compound (TAZ) is used in the luminescent layer and a phenanthroline derivative (HB-1) in the hole blocking layer. These compounds readily undergo crystallization or cohesion on account of their high symmetry and low molecular weight thereby deteriorating the thin film shape and, besides, their Tg is difficult to even observe because of high crystallinity. The instability of the thin film shape inside the luminescent layer like the one noted above exerts a bad influence such as shortening of the driving life of the element and lowering of the heat resistance. For the aforementioned reasons, a big problem facing organic EL elements utilizing phosphorescence at the present time is the driving stability of the element.

It is disclosed in JP2002-352957A that, in an organic EL element whose luminescent layer contains a host agent and a phosphorescent doping agent, a compound having an oxadiazole group is used as a host agent. In JP2001-230079A; an organic EL element having a thiazole or pyrazole structure in its organic layer is disclosed. In JP2001-313178A, an organic EL element having a luminescent layer containing a phosphorescent iridium complex and a carbazole compound is disclosed. In JP2003-45611A, an organic EL element having a luminescent layer containing a carbazole compound (PVK), a compound having an oxadiazole group (PBD) and Ir(Ppy)₃ is disclosed. In JP2002-158091A, ortho-metalated metal complexes and porphyrin metal complexes are proposed for phosphorescent compounds. However, the cited elements all face the aforementioned problems. It is to be noted that JP2001-230079A does not disclose an organic EL element utilizing phosphorescence.

### DISCLOSURE OF THE INVENTION

In contemplating applications of organic EL elements utilizing phosphorescence to display elements such as flat panel displays and illumination, the essential requirement is to improve the driving stability and heat resistance. Under the circumstances, an object of this invention is to provide an organic EL element showing high efficiency and good driving stability.

The inventors of this invention have conducted extensive studies, found that the aforementioned problems can be solved by using specified compounds in the luminous or electron transporting layer or in the hole blocking layer and completed this invention.

Accordingly, this invention relates to an organic electroluminescent element comprising a substrate, an anode, an organic layer and a cathode placed in layer one upon another wherein an azole compound having an oxadiazole structure represented by the following formula I and a triazole structure represented by the following formula II in the same molecule are incorporated in at least one layer in the organic layer: 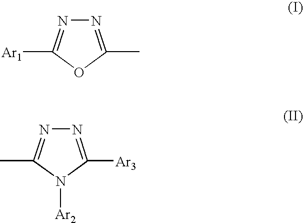
in formulas I and II, Ar₁-Ar₃ are independently substituted or unsubstituted aromatic hydrocarbon groups or aromatic heterocyclic groups; when the structure of formula I is a divalent group, Ar₁ denotes a single bond and, when the structure of formula II is a divalent or trivalent group, one or both of Ar₂ and Ar₃ denote a single bond.

Preferred examples of such azole compounds are represented by the following formulas IV to VIII: 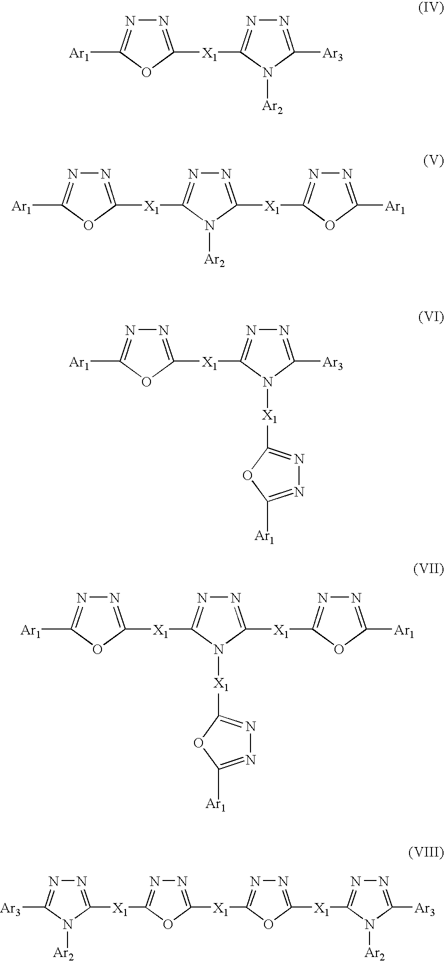
in these formulas, Ar₁-Ar₃ are independently substituted or unsubstituted aromatic hydrocarbon groups or aromatic heterocyclic groups and X₁ is a divalent aromatic hydrocarbon group.

Further, this invention relates to an organic electroluminescent element wherein at least one layer in the organic layer is a luminescent layer containing a host agent and a doping agent and any one of the aforementioned azole compounds is used as the host agent.

The doping agent preferably contains at least one compound selected from phosphorescent ortho-metalated metal complexes and porphyrin metal complexes. Preferably, the organic metal complexes contain at least one metal selected from the groups 7 to 11 of the periodic table at the center.

Further, this invention relates to an organic EL element wherein any one of the aforementioned azole compounds is incorporated in the hole blocking layer or electron transporting layer.

The organic electroluminescent element (organic EL element) of this invention has at least one organic layer positioned between the positive and cathodes on a substrate and at least one layer in this organic layer contains a specified azole compound. The layer in which the azole compound is incorporated is preferably the luminescent layer, hole blocking layer or electron transporting layer.

When incorporated in the luminescent layer, the azole compound exists as a host agent and contains a phosphorescent doping agent; normally, the azole compound is the main component and the doping agent a minor component. Here, the main component means a compound that accounts for 50 wt % or more of the material constituting the layer in question and the minor component means other compounds. Any compound useful for a host agent has an excited triplet level higher in energy than that of a phosphorescent doping agent. The use of the azole compound as a host agent is described below.

A candidate compound for a host agent in the luminescent layer according to this invention is required to be stable when formed into a thin film, have a high glass transition temperature (Tg) and be capable of efficiently transporting holes and/or electrons. Furthermore, the compound is required to be electrochemically and chemically stable and generate little impurities during manufacture or use that become traps or quench luminescence. A compound meeting these requirements is the one having both the 1,3,4-oxadiazole and 1,2,4-triazole structures represented respectively by the aforementioned formulas I and II (hereinafter referred to as azole compound).

In formulas I and II, Ar₁—Ar₃ are as defined earlier and the preferred groups for them are described below. The three groups Ar₁—Ar₃ may be identical with or different from one another.

The group Ar₁ is preferably an aromatic hydrocarbon group containing 1 to 3 rings and it may be substituted, preferably, by a lower alkyl group containing 1 to 5 carbon atoms. The number of substituents is preferably in the range of 0-3. Examples of such an aromatic hydrocarbon group are phenyl, 2-methylphenyl, 3-methylphenyl, 4-methylphenyl, 2,4-dimethylphenyl, 3,4-dimethylphenyl, 4-ethylphenyl, 2,4,5-trimethylphenyl, 4-tert-butylphenyl, 1-naphthyl, 9-anthracenyl and 9-phenanthrenyl. The group Ar₂ is preferably an aromatic hydrocarbon group containing 1 to 3 rings and it may be substituted, preferably, by a lower alkyl group containing 1 to 5 carbon atoms. The number of substituents is preferably in the range of 0-3. Examples are phenyl, 2-methylphenyl, 3-methylphenyl, 4-methylphenyl, 2,4-dimethylphenyl, 3,4-dimethylphenyl, 2,3-dimethylphenyl, 2,5-dimethylphenyl, 2,6-dimethylphenyl, 3,5-dimethylphenyl, 4-ethylphenyl, 2-sec-butylphenyl, 2-tert-butylphenyl, 4-n-butylphenyl, 4-sec-butylphenyl, 4-tert-butylphenyl, 1-naphthyl, 2-naphthyl, 1-anthracenyl, 2-anthracenyl and 9-phenanthrenyl.

The group Ar₃ is preferably an aromatic hydrocarbon group containing 1 to 3 rings and it may be substituted, preferably, by a lower alkyl group containing 1 to 5 carbon atoms. The number of substituents is preferably in the range of 0-3. Examples are phenyl, 2-methylphenyl, 3-methylphenyl, 4-methylphenyl, 2-ethylphenyl, 4-ethylphenyl, 2,3-dimethylphenyl, 2,4-dimethylphenyl, 2,5-dimethylphenyl, 2,6-dimethylphenyl, 3,4-dimethylphenyl, 3,5-dimethylphenyl, 2,4,5-trimethylphenyl, 2,4,6-trimethylphenyl, 4-n-propylphenyl, 4-sec-butylphenyl, 4-tert-butylphenyl, 1-naphthyl, 2-naphthyl and 9-anthracenyl.

An azole compound to be used in this invention has both the 1,3,4-oxadiazole and 1,2,4-triazole structures in the molecule; the number of each structure is 1 or more and preferably 1 to 2 of each structure or 2 to 4 in total.

In the cases where the number of the 1,3,4-oxadiazole and 1,2,4-triazole structures totals 3 or more and one or more of these structures are positioned midway, the groups having the 1,3,4-oxadiazole or 1,2,4-triazole structure become divalent or trivalent and, in accord with the valence of the azole structure, Ar₁—Ar₃ become single bonds or they cease to exist. The group Ar₁ becomes a single bond when the 1,3,4-oxadiazole structure represented by formula I becomes a divalent group and one or both of Ar₂ and Ar₃ become single bonds when the 1,2,4-triazole structure represented by formula II becomes a divalent or trivalent group. It is generally preferable that 2 or 3 of the structures represented by formulas I and II exist as monovalent groups.

The compounds represented by the aforementioned general formulas IV to VIII are cited as preferred azole compounds. In general formulas IV to VIII, Ar₁—Ar₃ are as defined in general formulas I and II earlier, but they never become single bonds. The group X₁ is a divalent coupling group and consists of a divalent aromatic hydrocarbon group. An aromatic hydrocarbon group containing 1 to 2 rings is preferable as a divalent coupling group and its examples are 1,4-phenylene, 1,3-phenylene, 1,4-naphthylene, 2,6-naphthylene and 4,4′-biphenylene.

The azole compounds useful for this invention are characterized by having both oxadiazole and triazole structures. According to the information available to date, compounds in which the oxadiazole structure or the triazole structure exists singly (for example, PBD and TAZ) are highly crystalline, unstable when formed into thin films and unsuited for practical use as materials for organic EL elements. The high crystallinity here is presumably due to a strong intermolelcular interaction because of the presence of highly polar functional groups such as oxadiazole and triazole. This consideration supports an assumption that the designed coexistence of different kinds of highly polar functional groups in a molecule endows the molecule with a function of canceling each other's polarity and suppressing the intermolecular interaction and results in improved stability of thin film.

Preferred examples of the compounds represented by formula IV are listed in Tables 1 to 4. Likewise, preferred examples of the compounds represented by formulas V, VI, VII and VIII are respectively listed in Tables 5 to 7, Tables 8 to 10, Tables 11 to 12 and Tables 13 to 14. However, it is to be noted that the compounds useful for this invention are not limited to those listed. The groups Ar₁, X₁, Ar₂ and Ar₃ in Tables 1 to 14 correspond to those in formulas IV to VIII.

Examples of the compounds represented by formula IV

TABLE 1

| No. | Ar1 | X1 | Ar2 | Ar3 |
|---|---|---|---|---|
| 1 | 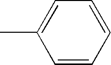 | 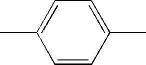 | 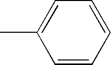 | 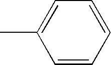 |
| 2 | 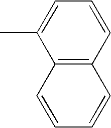 | 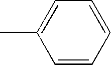 | 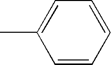 | 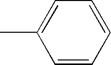 |
| 3 | 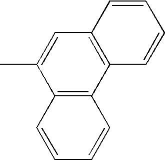 | 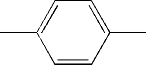 | 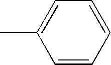 | 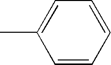 |
| 4 | 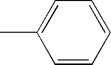 | 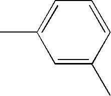 | 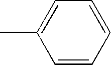 | 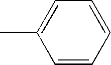 |
| 5 | 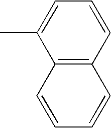 | 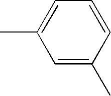 | 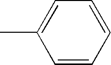 | 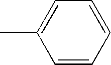 |
| 6 | 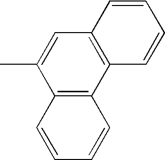 | 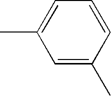 | 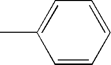 | 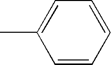 |
| 7 | 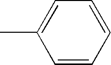 | 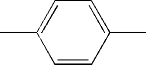 | 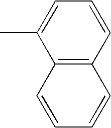 | 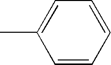 |
| 8 | 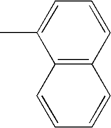 | 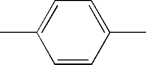 | 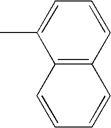 | 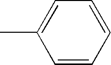 |
| 9 | 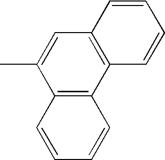 | 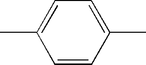 | 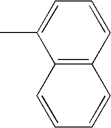 | 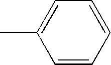 |
| 10 | 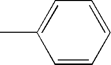 | 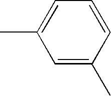 | 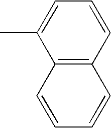 | 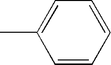 |
| 11 | 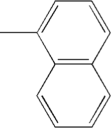 | 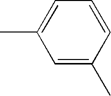 | 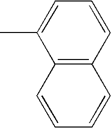 | 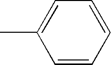 |

TABLE 2

| | | | | |
|---|---|---|---|---|
| 12 | 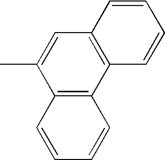 | 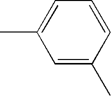 | 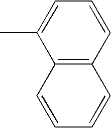 | 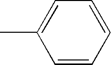 |
| 13 | 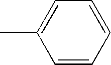 | 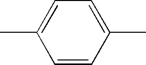 | 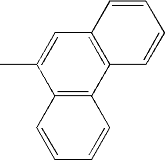 | 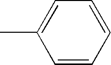 |
| 14 | 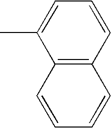 | 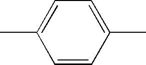 | 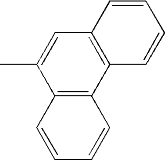 | 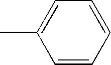 |
| 15 | 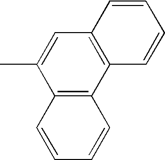 | 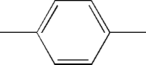 | 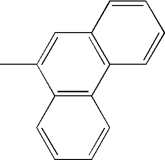 | 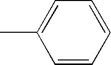 |
| 16 | 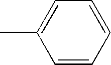 | 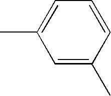 | 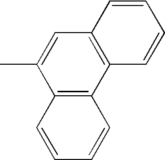 | 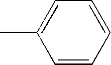 |
| 17 | 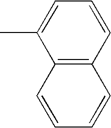 | 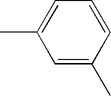 | 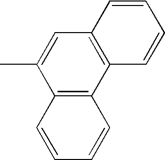 | 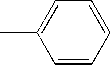 |
| 18 | 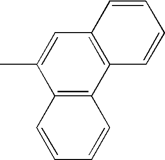 | 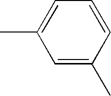 | 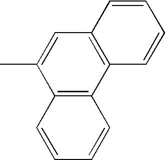 | 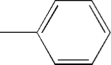 |
| 19 | 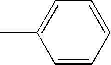 | 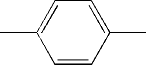 | 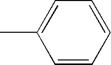 | 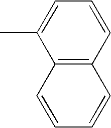 |
| 20 | 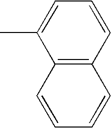 | 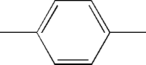 | 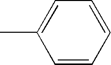 | 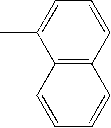 |
| 21 | 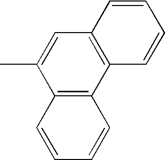 | 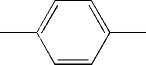 | 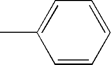 | 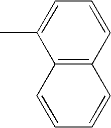 |

TABLE 3

| | | | | |
|---|---|---|---|---|
| 22 | 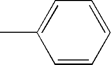 | 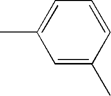 | 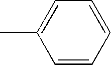 | 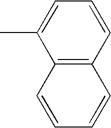 |
| 23 | 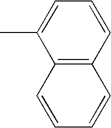 | 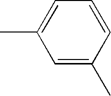 | 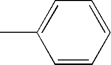 | 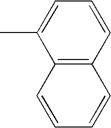 |
| 24 | 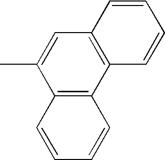 | 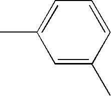 | 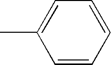 | 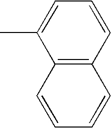 |
| 25 | 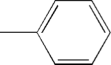 | 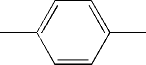 | 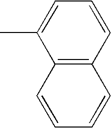 | 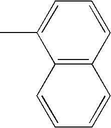 |
| 26 | 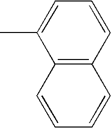 | 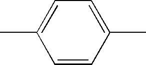 | 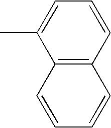 | 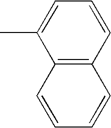 |
| 27 | 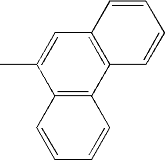 | 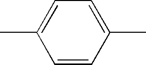 | 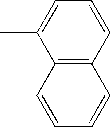 | 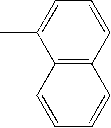 |
| 28 | 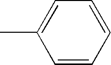 | 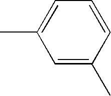 | 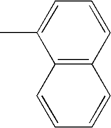 | 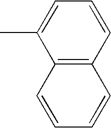 |
| 29 | 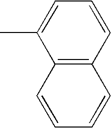 | 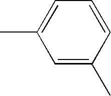 | 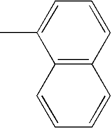 | 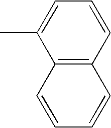 |
| 30 | 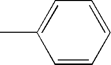 | 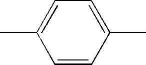 | 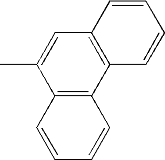 | 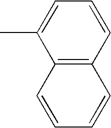 |
| 31 | 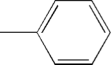 | 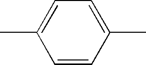 | 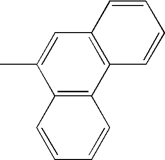 | 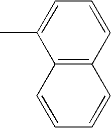 |

TABLE 4

| | | | | |
|---|---|---|---|---|
| 32 | 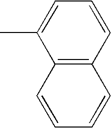 | 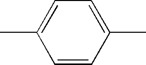 | 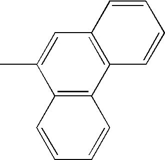 | 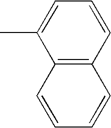 |
| 33 | 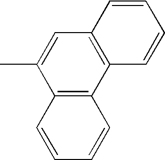 | 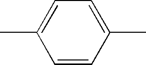 | 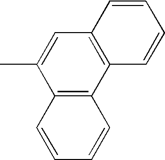 | 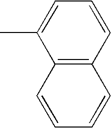 |
| 34 | 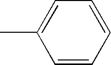 | 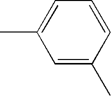 | 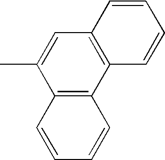 | 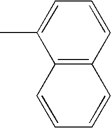 |
| 35 | 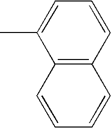 | 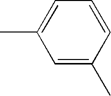 | 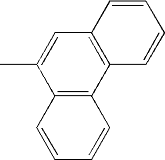 | 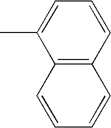 |
| 36 | 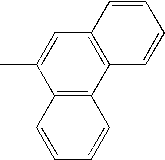 | 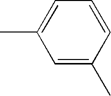 | 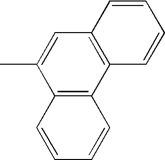 | 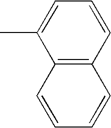 |

Examples of the compounds represented by formula V

TABLE 5

| No. | Ar1 | X1 | Ar2 | Ar3 |
|---|---|---|---|---|
| 37 | 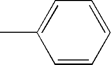 | 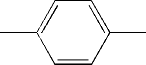 | 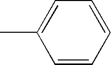 | — |
| 38 | 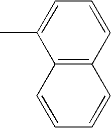 | 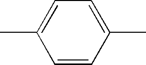 | 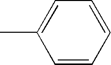 | — |
| 39 | 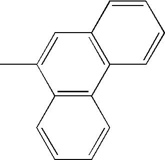 | 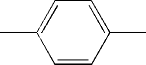 | 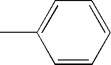 | — |
| 40 | 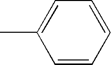 | 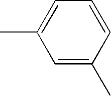 | 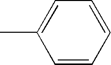 | — |

TABLE 6

| | | | | |
|---|---|---|---|---|
| 41 | 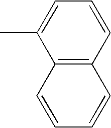 | 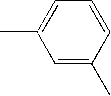 | 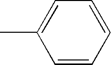 | — |
| 42 | 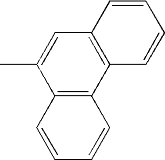 | 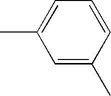 | 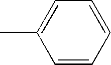 | — |
| 43 | 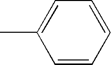 | 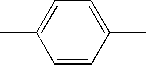 | 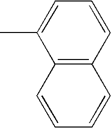 | — |
| 44 | 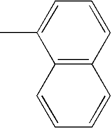 | 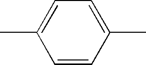 | 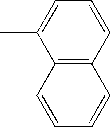 | — |
| 45 | 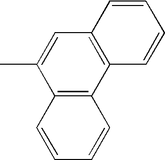 | 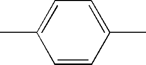 | 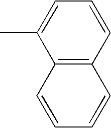 | — |
| 46 | 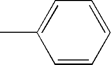 | 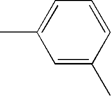 | 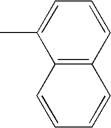 | — |
| 47 | 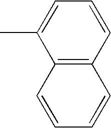 | 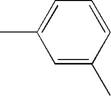 | 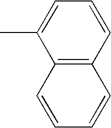 | — |
| 48 | 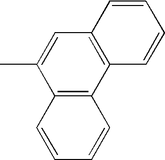 | 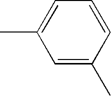 | 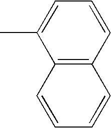 | — |
| 49 | 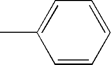 | 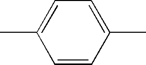 | 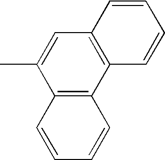 | — |
| 50 | 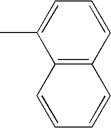 | 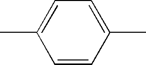 | 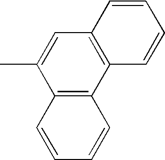 | — |

TABLE 7

| | | | | |
|---|---|---|---|---|
| 51 | 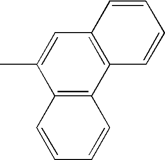 | 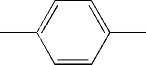 | 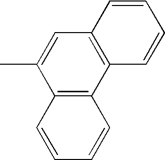 | — |
| 52 | 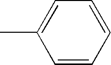 | 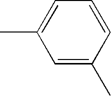 | 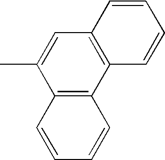 | — |
| 53 | 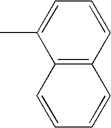 | 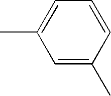 | 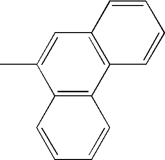 | — |
| 54 | 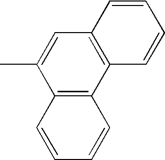 | 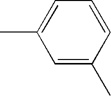 | 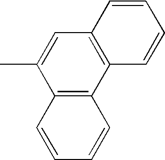 | — |

Examples of the compounds represented by formula VI

TABLE 8

| | | | | |
|---|---|---|---|---|
| No. | Ar1 | X1 | Ar2 | Ar3 |

| | | | | |
|---|---|---|---|---|
| 55 | 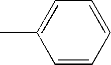 | 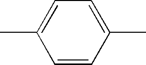 | — | 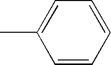 |
| 56 | 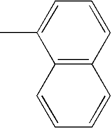 | 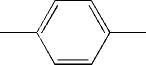 | — | 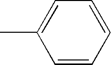 |
| 57 | 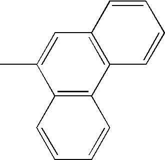 | 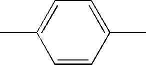 | — | 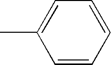 |
| 58 | 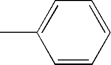 | 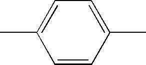 | — | 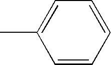 |
| 59 | 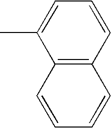 | 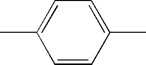 | — | 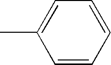 |

TABLE 9

| | | | | |
|---|---|---|---|---|
| 60 | 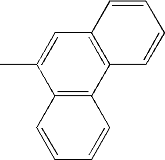 | 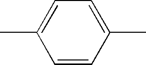 | — | 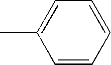 |
| 61 | 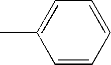 | 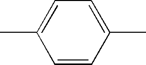 | — | 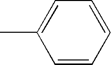 |
| 62 | 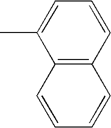 | 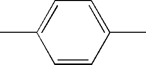 | — | 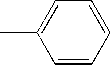 |
| 63 | 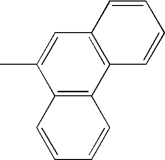 | 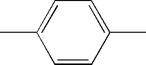 | — | 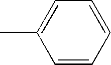 |
| 64 | 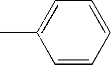 | 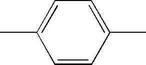 | — | 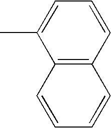 |
| 65 | 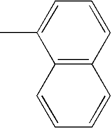 | 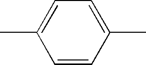 | — | 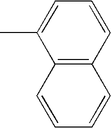 |
| 66 | 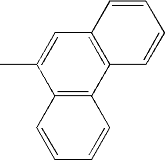 | 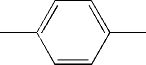 | — | 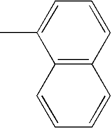 |
| 67 | 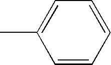 | 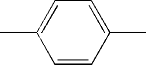 | — | 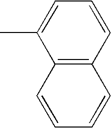 |
| 68 | 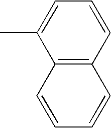 | 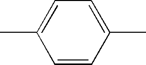 | — | 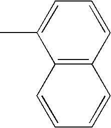 |
| 69 | 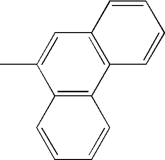 | 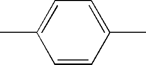 | — | 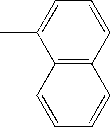 |
| 70 | 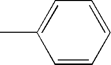 | 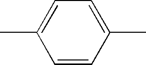 | — | 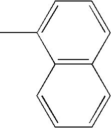 |

TABLE 10

| | | | | |
|---|---|---|---|---|
| 71 | 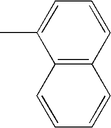 | 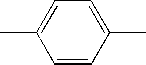 | — | 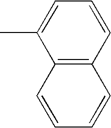 |
| 72 | 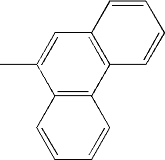 | 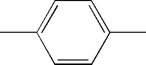 | — | 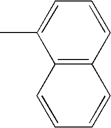 |

Examples of the compounds represented by formula VII

TABLE 11

| No. | Ar1 | X1 | Ar2 | Ar3 |
|---|---|---|---|---|
| 73 | 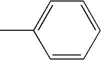 | 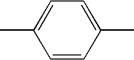 | — | — |
| 74 | 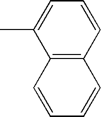 | 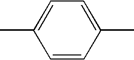 | — | — |
| 75 | 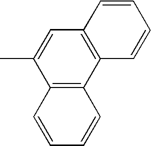 | 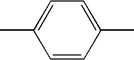 | — | — |
| 76 | 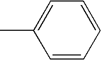 | 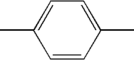 | — | — |
| 77 | 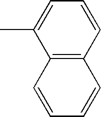 | 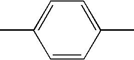 | — | — |
| 78 | 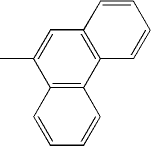 | 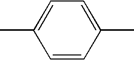 | — | — |
| 79 | 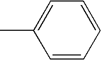 | 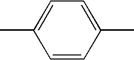 | — | — |
| 80 | 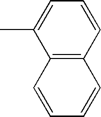 | 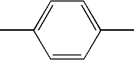 | — | — |

TABLE 12

| | | | | |
|---|---|---|---|---|
| 81 | 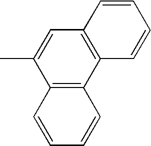 | 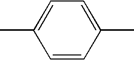 | — | — |
| 82 | 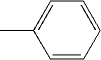 | 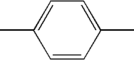 | — | — |
| 83 | 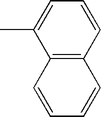 | 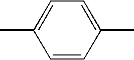 | — | — |
| 84 | 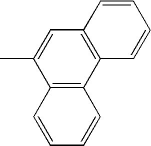 | 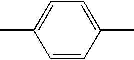 | — | — |
| 85 | 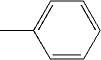 | 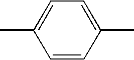 | — | — |
| 86 | 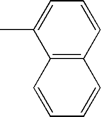 | 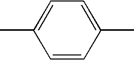 | — | — |
| 87 | 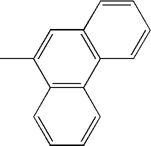 | 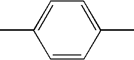 | — | — |
| 88 | 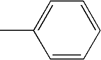 | 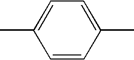 | — | — |
| 89 | 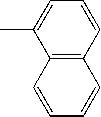 | 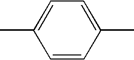 | — | — |
| 90 | 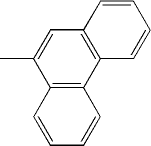 | 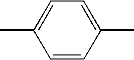 | — | — |

Examples of the compounds represented by formula VIII

TABLE 13

| No. | Ar1 | X1 | Ar2 | Ar3 |
|---|---|---|---|---|
| 91 | — | 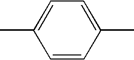 | 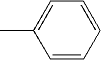 | 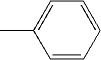 |
| 92 | — | 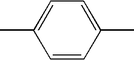 | 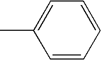 | 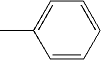 |
| 93 | — | 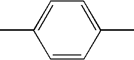 | 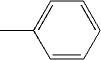 | 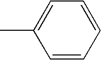 |
| 94 | — | 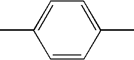 | 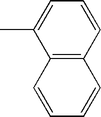 | 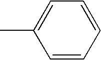 |
| 95 | — | 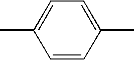 | 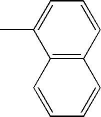 | 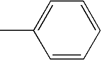 |
| 96 | — | 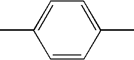 | 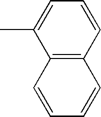 | 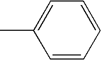 |
| 97 | — | 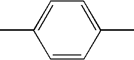 | 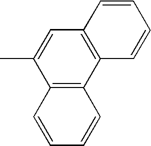 | 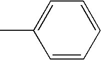 |
| 98 | — | 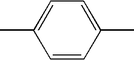 | 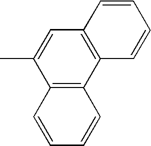 | 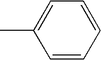 |
| 99 | — | 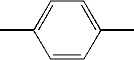 | 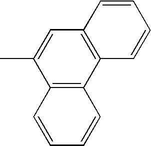 | 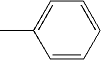 |
| 100 | — | 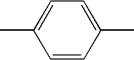 | 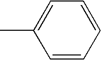 | 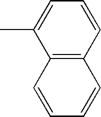 |
| 101 | — | 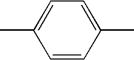 | 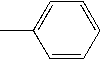 | 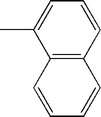 |
| 102 | — | 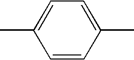 | 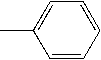 | 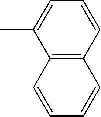 |

TABLE 14

| | | | | |
|---|---|---|---|---|
| 103 | — | 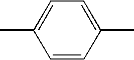 | 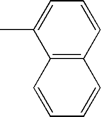 | 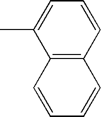 |
| 104 | — | 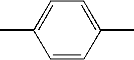 | 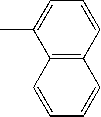 | 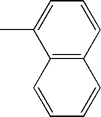 |
| 105 | — | 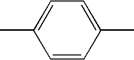 | 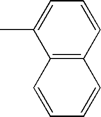 | 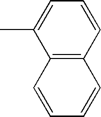 |
| 106 | — | 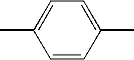 | 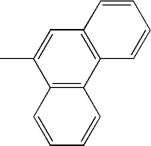 | 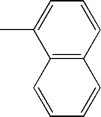 |
| 107 | — | 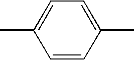 | 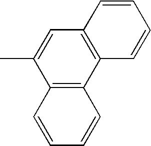 | 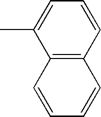 |
| 108 | — | 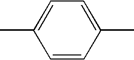 | 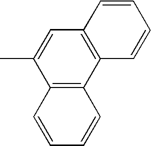 | 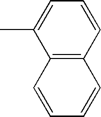 |

When the luminescent layer of an organic EL element of this invention contains one of the aforementioned host agents, it additionally contains the minor component or a phosphorescent doping agent. Any one of the publicly known phosphorescent metal complexes described in the aforementioned literatures, preferably those containing a metal selected from the groups 7 to 11 of the periodic table at the center of the complex, can be used as a doping agent. The metal in question is preferably selected from ruthenium, rhodium, palladium, silver, rhenium, osmium, iridium, platinum and gold. These doping agents and metals may be used singly or as a mixture of two kinds or more.

The phosphorescent doping agents are publicly known as described in JP2002-352957A and elsewhere. Moreover, the phosphorescent doping agents are preferably phosphorescent ortho-metalated metal complexes or porphyrin metal complexes which are publicly known as described in JP2002-158091A and elsewhere. Therefore, these publicly known phosphorescent doping agents can be used freely.

The following compounds may be cited as examples of desirable organic metal complexes; Ir(Ppy)₃ and others containing a noble metal such as Ir at the center (formula A), Ir(bt)₂·acac₃ and others (formula B) and PtOEt₃ and other (formula C).

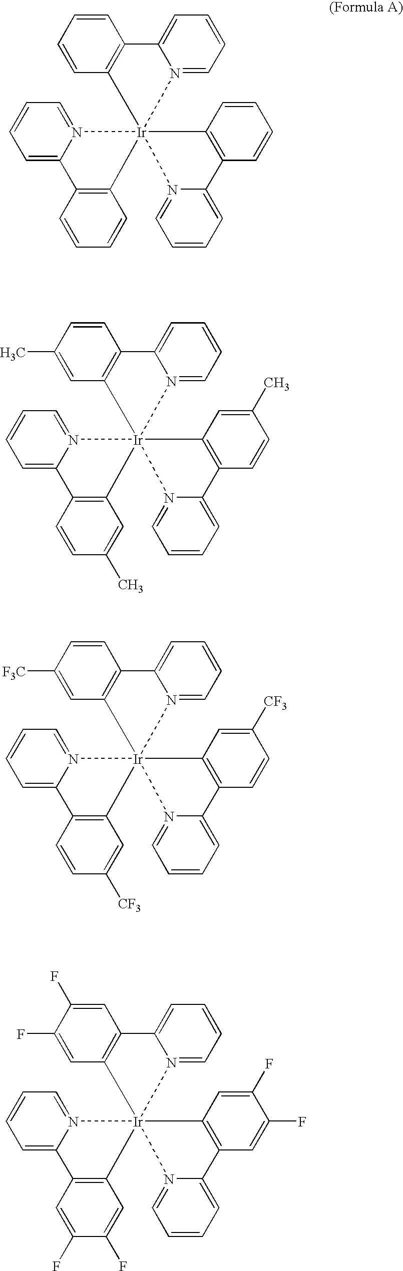

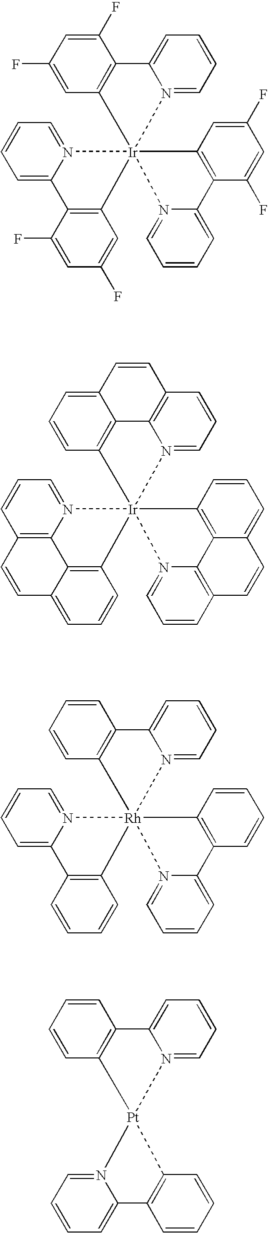

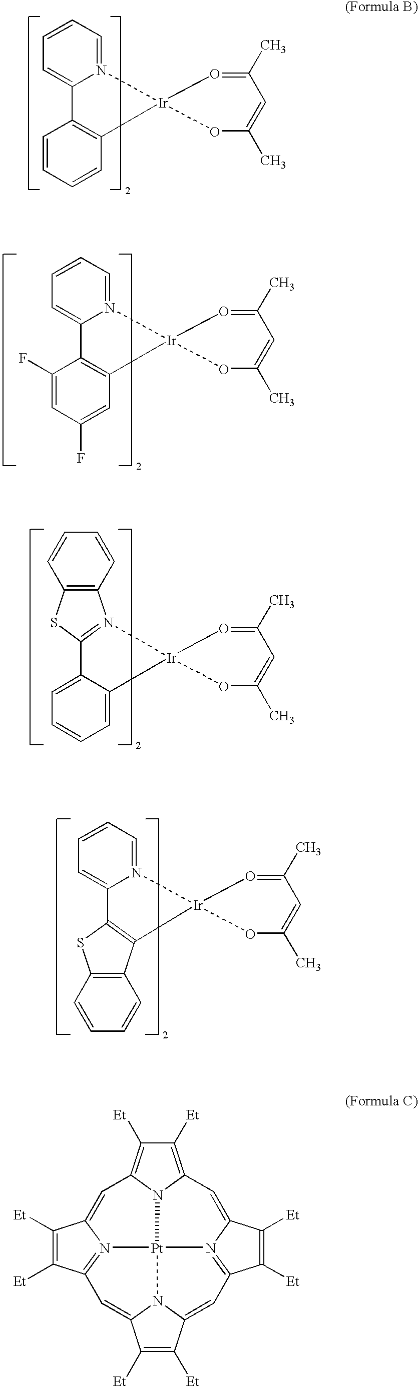

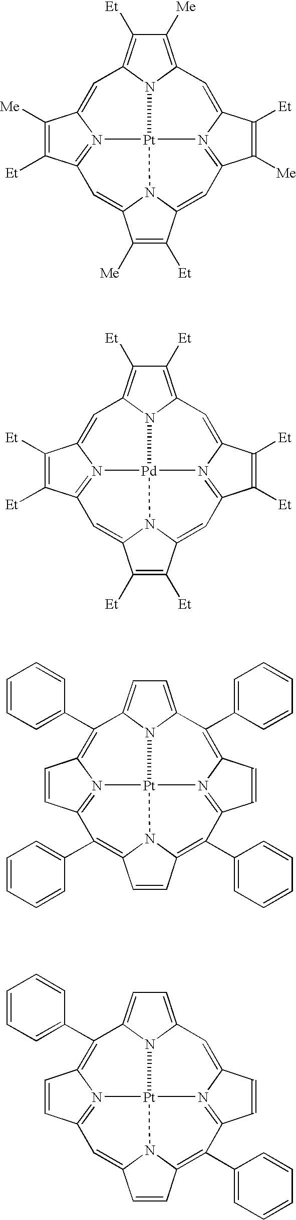

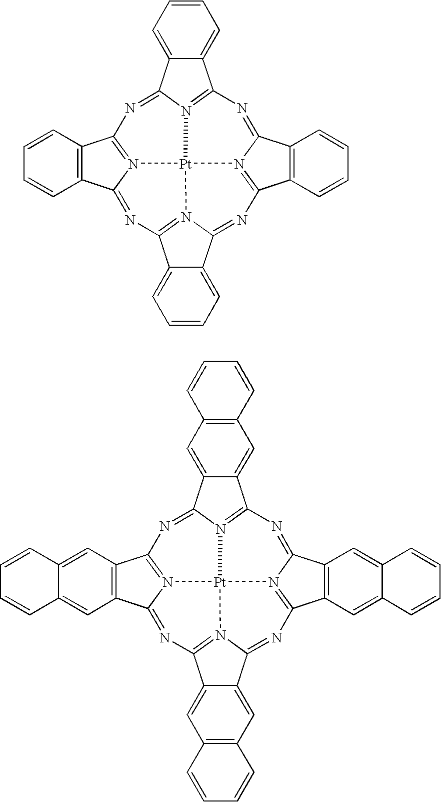

The azole compound may be incorporated in a layer other than the luminescent layer and, in such a case, the compound to be incorporated in the luminescent layer may be a publicly known luminous material and may not contain a doping agent. The aforementioned layer other than the luminescent layer is preferably the hole blocking layer or the electron transporting layer; however, depending upon the composition of layers, the azole compound may also be incorporated in another layer or it may be incorporated together with other compounds or in a plurality of layers.

### BRIEF DESCRIPTION OF THE DRAWING

FIG. 1 is a schematic drawing to illustrate the layered structure of an organic EL element. On a substrate 1 are placed an anode 2, a hole injecting layer 3, a hole transporting layer 4, a luminescent layer 5, a hole blocking layer 6, an electron transporting layer 7 and a cathode 8 in layer one upon another.

### PREFERRED EMBODIMENTS OF THE INVENTION

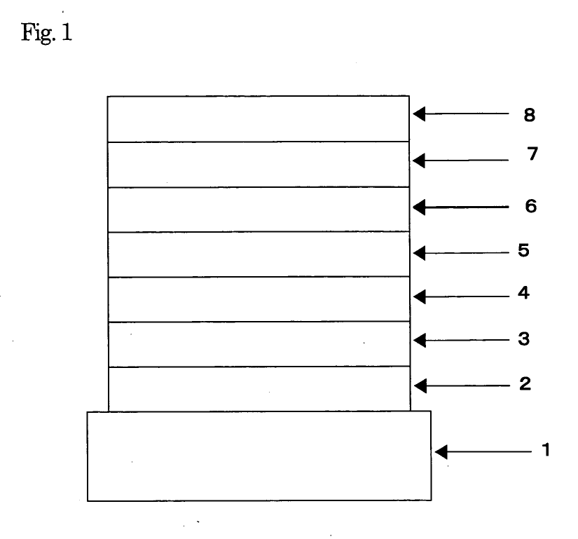

An example of the organic EL element of this invention is described below with reference to the drawing. FIG. 1 is a cross section which schematically illustrates the structure of a common organic El element to be used in this invention: 1 denotes a substrate, 2 an anode, 3 a hole injecting layer, 4 a hole transporting layer, 5 a luminescent layer, 6 a hole blocking layer, 7 an electron transporting layer and 8 a cathode. Normally, the layers from 3 to 7 are organic layers and the organic EL element of this invention comprises one or more layers inclusive of the luminescent layer 5 of these organic layers. It is advantageous that the organic EL element of this invention comprises three or more organic layers, preferably five or more organic layers, inclusive of the luminescent layer 5. FIG. 1 is one example and it is allowable to add or omit one or more layers.

The substrate 1 supports an organic El element and a quartz or glass plate, a metallic plate or foil or a plastic film or sheet is used for it. In particular, plates of glass and transparent synthetic resins such as polyester, polymethacrylate, polycarbonate and polysulfone are desirable. When a synthetic resin substrate is used, its gas barrier property needs to be taken into consideration. When the substrate shows a poor gas barrier property, the air may pass through the substrate and undesirably degrades the organic EL element. One convenient method to secure the desired gas barrier property is to provide a dense silicon oxide film on at least one side of the synthetic resin substrate.

The anode 2 is provided on the substrate 1 and this plays a role of injecting holes to the hole transporting layer. This anode is usually constituted of a metal such as aluminum, gold, silver, nickel, palladium and platinum, a metal oxide such as the oxide of indium and/or tin, a metal halide such as copper iodide, carbon black or an electrically conductive polymer such as poly(3-methylthiophene), polypyrrole and polyaniline. Usually, processes such as sputtering and vacuum deposition are most often used in forming the anode 2. Alternatively, the following methods may be used: where metals such as silver, copper iodide, carbon black, electrically conductive metal oxides or electrically conductive polymers are available in fine particles, the particles are dispersed in a solution of a suitable binder resin and the dispersion is applied to the substrate 1 to form the anode 2; in the case of an electrically conductive polymer, the anode 2 is formed directly on the substrate 1 in thin film by electrolytically polymerizing the corresponding monomers or it is formed by coating the substrate 1 with the polymer. The anode 2 can also be formed in layer from different materials. The thickness of the anode 2 varies with the requirement for transparency. Where transparency is needed, the transmission of visible light is desirably kept normally at 60% or more, preferably at 80% or more and the thickness in this case is normally 5-1000 nm, preferably 10-500 nm. Where opaqueness is tolerated, the anode 2 may be identical with the substrate 1. Furthermore, it is possible to superimpose a different electrically conductive material on the anode 2.

One approach to the improvement of the hole injection efficiency and the adhesive strength of the whole organic layer to the anode is to insert the hole injecting layer 3 between the hole transporting layer 4 and the anode 2. The insertion of the hole injecting layer 3 is effective for lowering the initial driving voltage of the element and, at the same time, effective for suppressing a rise in voltage when the element is driven continuously at a constant electric current.

A material to be used for the hole injecting layer should meet the following requirements: it can be formed into a uniform thin film capable of making close contact with the anode; it is thermally stable, that is, it shows a high melting point, 300° C. or above, and a high glass transition temperature, 100° C. or above; furthermore, it has a low ionization potential which facilitates the injection of holes from the anode and shows high hole mobility.

A number of compounds have hitherto been reported as materials meeting these requirements; for example, phthalocyanine compounds such as copper phthalocyanine, organic compounds such as polyaniline and polythiophene, sputtered carbon films and metal oxides such as vanadium oxide, ruthenium oxide and molybdenum oxide. In the case of an anode buffer layer, it is formable into a thin film like the hole transporting layer. In the case of inorganic materials, the processes such as sputtering, electron beam deposition and plasma CVD are used. The thickness of the hole injecting layer 3 formed in the aforementioned manner is normally in the range of 3-100 nm, preferably in the range of 5-50 nm.

On the hole injecting layer 3 is provided the hole transporting layer 4. A material to be used for the hole transporting layer should accord with a high hole injection efficiency from the hole injecting layer 3 and efficiently transport the injected holes. Hence, the candidate material must meet the requirements of low ionization potential, high transmission of visible light, high hole mobility, good stability and generation of little hole-trapping impurities during manufacture or use. As the hole transporting layer 4 exists in contact with the luminescent layer 5, it is further required not to quench luminescence or not to lower the luminous efficiency by forming an exciplex between it and the luminous layer. In addition to the aforementioned general requirements, the element is required to be heat-resistant when an application as a vehicular display is considered. Therefore, a material with a Tg of 90° C. or above is preferable.

The materials of this kind include aromatic diamines that contain 2 or more tertiary amines substituted with aromatic groups composed of 2 or more condensed rings, typically 4,4′-bis[N-(1-naphthyl)-N-phenylamino]biphenyl, aromatic amines with a starburst structure such as 4,4′,4″-tris(1-naphthylphenylamino)triphenylamine, aromatic amines comprising tetramers of triphenylamine and spiro compounds such as 2,2′,7,7′-tetrakis(diphenylamino)-9,9′-spirobifluorene. These compounds may be used singly or as a mixture.

In addition to the aforementioned compounds, the materials useful for the hole transporting layer 4 include polymeric materials such as polyvinylcarbazole, polyvinyltriphenylamine and polyaryleneethersulfone containing tetraphenylbenzidine. When the coating process is adopted for the formation of the hole transporting layer 4, one kind or more of hole transport materials are mixed, if necessary, with a binder resin which does not become a trap of holes and an additive such as an improver of coating properties, the mixture is dissolved and the solution is applied to the anode 2 or the hole injecting layer 3 by a method such as spin coating and dried to form the hole transporting layer 4. The binder resins useful here include polycarbonate, polyarylate and polyester. As the binder resins lower the hole mobility when added in a large amount, they are normally added in a smaller amount, normally 50 wt % or less.

When the vacuum deposition process is adopted, a material for the hole transporting layer is introduced to a crucible placed in a vacuum container, the vacuum container is evacuated by a suitable vacuum pump to 10⁻⁴ Pa or so, the crucible is then heated and the vaporized material forms the hole transporting layer 4 on an anode on the substrate 1 which is placed face to face with the crucible. The thickness of the hole transporting layer 4 is normally 5-300 nm, preferably 10-100 nm. The vacuum deposition process is generally used where a uniform thin film needs to be formed.

On the hole transporting layer 4 is provided the luminescent layer 5. The luminescent layer 5 contains the aforementioned host agent and phosphorescent doping agent and becomes excited and emits light strongly when the holes which. are injected from the anode and moving through the hole transporting layer unite with the electrons which are injected from the cathode and moving through the electron transporting layer 7 (or the hole blocking layer 6) between the electrodes. where an electrical field is applied.

When an azole compound is incorporated as a host agent in the luminescent layer, a material to be used for the host agent in the luminescent layer is required to accord with high efficiencies in hole injection from the hole transporting layer 4 and electron injection from the electron transporting layer 7 (or the hole blocking layer 6). To meet these requirements, the candidate material must have an adequate value of ionization potential, show high mobility of holes and electrons, be electrically stable and generate little impurities during manufacture and use which may become traps of holes. The candidate material is further required not to lower the luminous efficiency by forming an exciplex between it and the adjacent hole transporting layer 4 or between it and the adjacent electron transporting layer (or the hole blocking layer 6). In addition to the aforementioned general requirements, the element is required to be heat-resistant when an application as a vehicular display is considered. Therefore, a material with a Tg of 90° C. or above is preferable. It is allowable for the luminescent layer to contain other components such as non-azole host materials and fluorescent dyes to the extent that its performance is not harmed.

In another mode of practice of this invention where an azole compound is not incorporated as a host agent in the luminescent layer, it is possible to use freely selected publicly known host materials and doping materials in the luminescent layer and it is also possible to use a single luminescent material without resorting to a combination of host and guest materials. In this case, the azole compound is incorporated either in the hole blocking layer or in the electron transporting layer.

In the cases where one of the organic metal complexes represented by the aforementioned formulas A to C is used as a doping agent, its content in the luminescent layer is preferably in the range of 0.1-30 wt %. The use of less than 0.1 wt % does not contribute to an improvement in the luminous efficiency of the element. On the other hand, the use in excess of 30 wt % causes quenching of light as the organic metal complexes dimerize, which results in lowering of the luminous efficiency. The content of the organic metal complex shows a tendency to be somewhat larger than that of a fluorescent dye (dopant) in the luminescent layer of the conventional elements utilizing fluorescence (singlet). The organic metal complex in the luminescent layer may be contained partially in the direction of film thickness or it may be distributed non-uniformly. The thickness of the luminescent layer 5 is normally 10-200 nm, preferably 20-100 nm. The thin film here is formed by the same method as used for the hole transporting layer 4.

The luminescent layer 5 is advantageously formed by the vacuum deposition process. The host agent and the doping agent are both introduced in a crucible placed in a vacuum container, the vacuum container is evacuated by a suitable vacuum pump to 10⁻⁴ Pa or so and the crucible is heated to vaporize both the host and doping agents to form a thin film on the hole transporting layer 4. During this time, the content of the doping agent in the host agent is controlled by separately monitoring the rate of deposition of the host agent and that of the doping agent.

The hole blocking layer 6 is placed in contact with the interface of the luminescent layer 5 on the cathode side and it is made from a compound capable of inhibiting the holes that are moving from the hole transporting layer from reaching the cathode and efficiently transporting the electrons injected from the cathode to the luminescent layer. The properties required for a material constituting the hole blocking layer are high electron mobility and low hole mobility. The hole blocking layer 6 has a function of confining holes and electrons in the luminescent layer and improving the luminous efficiency.

The electron transporting layer 7 is made from a compound capable of transporting the electrons injected from the cathode efficiently toward the hole blocking layer 6 in an electrical field between the electrodes. A compound capable of transporting electrons and useful for the electron transporting layer 7 must accord with a high electron injection efficiency of the cathode 8 and have a high electron mobility to allow efficient transport of the injected electrons.

The materials satisfying these requirements include metal complexes such as 8-hydroxyquinoline aluminum complex, metal complexes of 10-hydroxybenzo[h]quinoline, oxadiazole derivatives, distyrylbiphenyl derivatives, silole derivatives, 3- or 5-hydroxyflavone metal complexes, benzoxazole metal complexes, benzothiazole metal complexes, tris(benzimidazolyl)benzene, quinoxaline compounds, phenanthroline derivatives, 2-t-butyl-9,10-N,N′-dicyanoanthraquinonediimine, n-type hydrogenated amorphous silicon carbide, n-type zinc sulfide and n-type zinc selenide. The thickness of the electron transporting layer 7 is normally 5-200 nm, preferably 10-100 nm.

The electron transporting layer 7 is formed on the hole blocking layer 6 by the coating process or the vacuum deposition process as in the case of the hole transporting layer 4. The vacuum deposition process is usually used.

The cathode 8 plays a role of injecting electrons to the luminescent layer 5. A material useful for the cathode 8 may be the same material as for the aforementioned anode 2. However, a metal with a low work function is helpful to efficient injection of electrons; for example, tin, magnesium, indium, calcium, aluminum and silver as metal or alloy. Examples are alloy electrodes with a low work function such as magnesium-silver alloy, magnesium-indium alloy and aluminum-lithium alloy. Furthermore, insertion of an ultra thin insulating film (0.1-5 nm) of LiF, MgF₂, Li₂O and the like to the interface of the cathode and the electron transporting layer provides an efficient method for improving the efficiency of the element. The thickness of the cathode 8 is normally the same as the anode 2. Laminating a metal layer that has a high work function and is stable against the atmosphere to a cathode composed of a metal of a low work function protects the cathode and further increases the stability of the element. To this end, a metal such as aluminum, silver, copper, nickel, chromium, gold and platinum is used.

Furthermore, it is possible to reverse the order shown in FIG. 1 in building up the layers; for example, substrate 1/cathode 8/hole blocking layer 6/luminescent layer 5/hole transporting layer 4/anode 2 or substrate 1/cathode 8/electron transporting layer 7/hole blocking layer 6/luminescent layer 5/hole transporting layer 4/hole injecting layer 3/anode 2.

### EXAMPLES

### Synthetic Example 1

### Synthesis of 3-[4-(phenyl-1,3,4-oxadiazolyl-(5))-phenyl]-4,5-diphenyl-1,2,4-triazole (Hereinafter Referred to as POT)

The reactions involved in the synthesis are shown below.

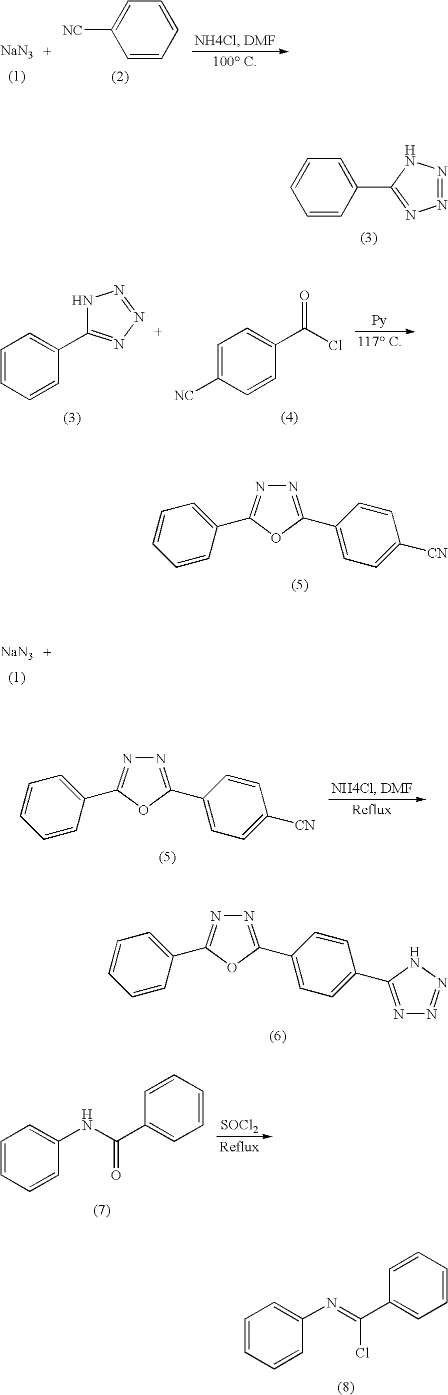

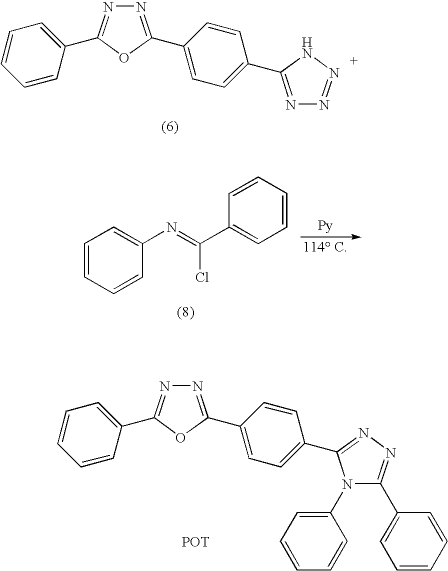

The reaction of compound (6) with compound (8) to give POT is described below.

In a 1000-ml four-necked flask were placed 43.6 g (0.150 mole) of compound (6), 64.8 g (0.300 mole) of compound (8) and 493.1 g of pyridine and the mixture was heated to 114° C. and heated there under reflux for 2 hours. After the reaction, the reaction mixture was thrown into 3000 ml of methanol and the precipitated crystals were collected by filtration, washed with 1500 ml of methanol and dried at 100° C. under reduced pressure to give 1.3 g of dried crystals. The crystals were recrystallizerd three times from dimethylformamide to give 31.0 g of purified crystals of POT; purity 99.97% (HPLC area ratio), mass analysis value 441, melting point 273.0° C., yield 46.8%. POT is compound No.1 in Table 1.

The result of the IR analysis of POT is shown below.

IR (KBr) 3432, 3060, 1614, 1578, 1548, 1496, 1470, 1450, 1424, 1400, 1270, 1070, 1018, 972, 966, 848, 776, 740, 716, 694, 620, 608, 536, 492

### Synthetic Example 2

### Synthesis of 3,4-bis[4-(2-phenyl-1,3,4-oxadiazolyl-(5))-phenyl]-5-phenyl-1,2,4-triazole (Hereinafter Referred to as 3,4-BPOT)

The reactions involved in the synthesis are shown below.

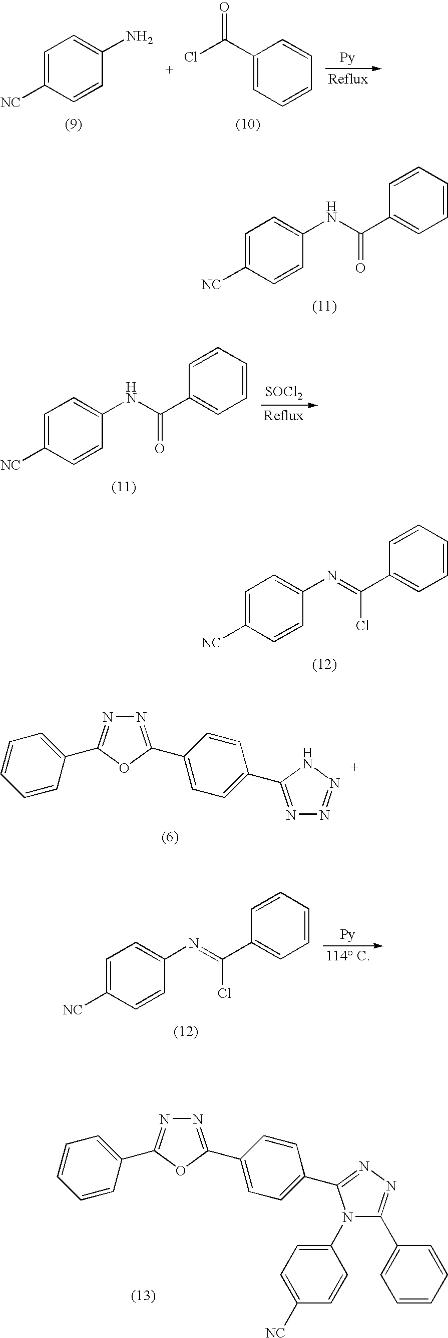

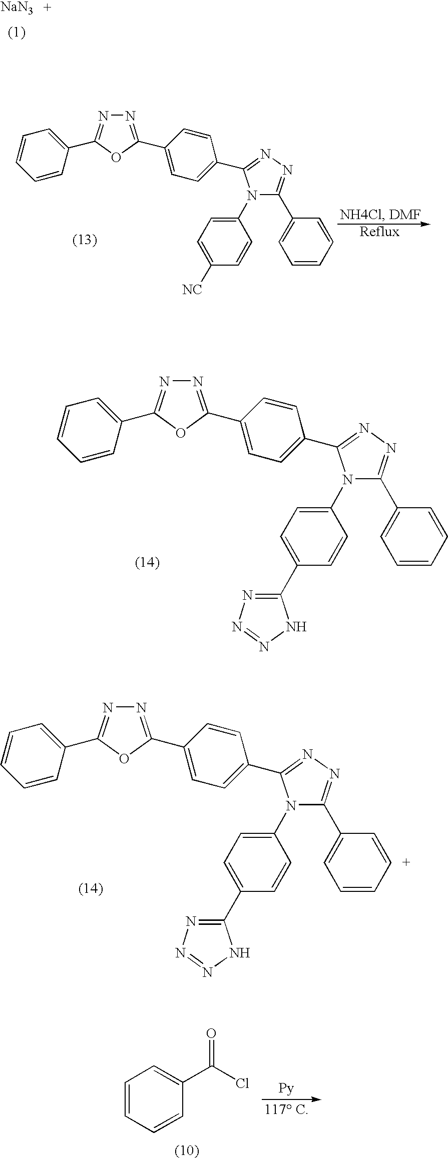

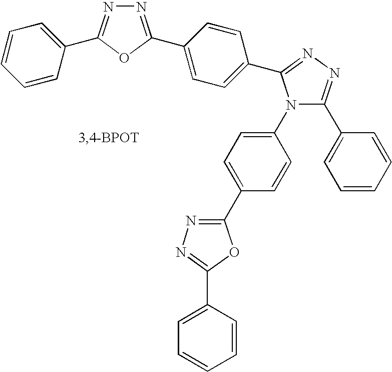

The reaction of compound (14) with compound (10) to give 3,4-BPOT is described below.

In a 200-ml four-necked flask were placed 6.1 g (0.011 mole) of compound (14), 4.9 g (0.034 mole) of compound (10) and 73.3 g of pyridine and the mixture was heated to 117° C. and heated there under reflux for 2 hours. After the reaction, 100.9 g of methanol was added to the mixture and the precipitated crystals were collected by filtration and recrystallized from methylene chloride to give 3.6 g of purified crystals of 3,4-BPOT: purity 99.16% (HPLC area ratio), mass analysis value 585, melting point 324.0° C., yield 55.9%. 3,4-BPOT is compound No. 55 in Table 8.

The result of the IR analysis of 3,4-BPOT is shown below.

IR (KBr) 3448, 3060, 2920, 2856, 1932, 1612, 1582, 1550, 1502, 1488, 1470, 1448, 1424, 1316, 1270, 1190, 1160, 1100, 1064, 1016, 990, 962, 924, 868, 850, 776, 746, 734, 712, 690, 638, 608, 532, 506, 488

### Synthetic Example 3

### Synthesis of 3,5-bis[4-(2-phenyl-1,3,4-oxadiazolyl-(5))-phenyl]-5-phenyl-1,2,4-triazole (Hereinafter Referred to as 3,5-BPOT)

The reactions involved in the synthesis are shown below.

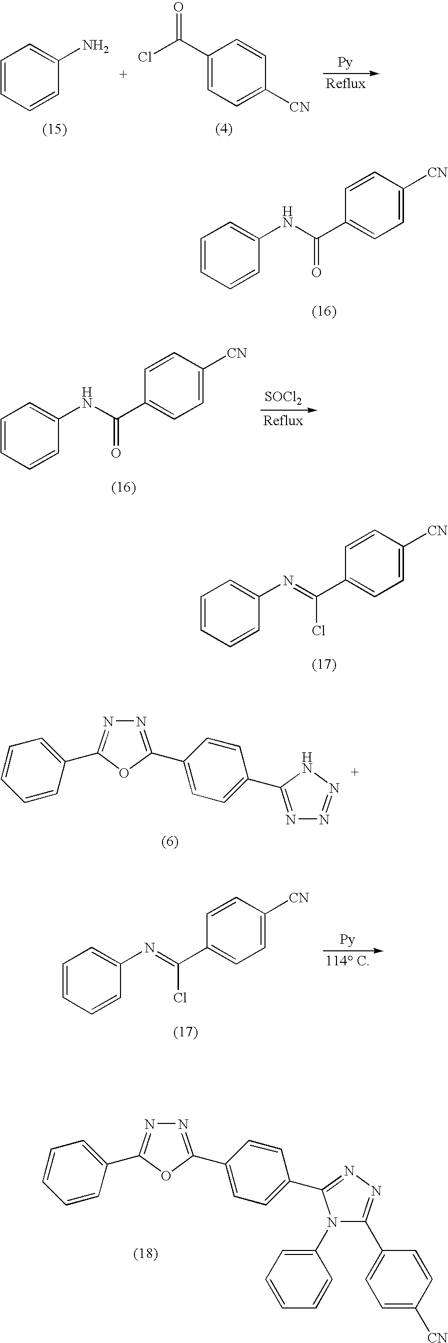

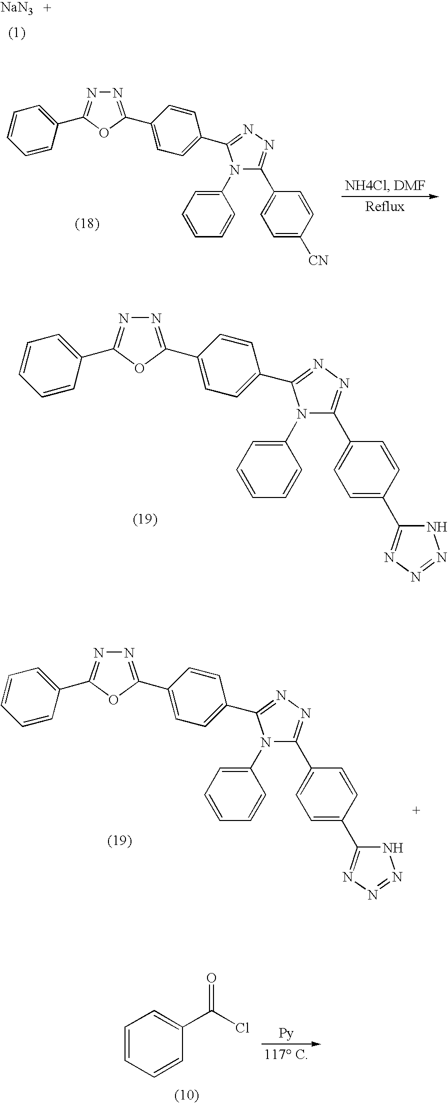

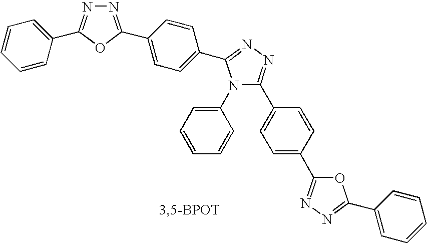

The reaction of compound (19) with compound (10) to give 3,5-BPOT is described below. In a 300-ml four-necked flask were placed 5.6 g (0.011 mole) of compound (19), 4.2 g (0.030 mole) of compound (10) and 87.9 g of pyridine and the mixture was heated to 117° C. and heated there under reflux for 2 hours. After the reaction, 136.5 g of methanol was added to the mixture and the precipitated crystals were collected by filtration and recrystallized from methylene chloride to give 3.3 g of purified crystals of 3,5-BPOT: purity 99.31% (HPLC area ratio), mass analysis value 585, melting point 344.1° C., yield 51.3%. 3,5-BPOT is compound No. 37 in Table 5.

The result of the IR analysis of 3,5-BPOT is shown below.

IR (KBr) 3452, 3060, 2924, 1612, 1548, 1472, 1450, 1412, 1314, 1270, 1174, 1152, 1104, 1066, 1026, 1016, 964, 924, 850, 780, 744, 714, 690, 640, 612, 534, 500

### Example 1

An organic EL element having the layered structure shown in FIG. 1 less the hole injecting layer 3 and the hole blocking layer 6 was prepared as follows. Using a vacuum deposition apparatus of resistance heating type, 4,4′-bis[N,N′-(3-tolyl)amino]-3,3′-dimethylbiphenyl (hereinafter referred to as HMTPD) was deposited to a film thickness of 60 nm to form the hole transporting layer 4 on a cleaned ITO electrode (anode 2) with an electrode area of 2×2 mm² provided on the glass substrate 1 (available from Sanyo Vacuum Industries Co., Ltd.) while controlling the rate of deposition by an ULVAC quartz-crystal oscillator film thickness monitor and keeping the vacuum at (7-9)×10⁻⁴ Pa. Using the same vacuum deposition apparatus without breaking the vacuum, the luminescent layer 5 was formed in a film thickness of 25 nm on the hole transporting layer 4 by depositing simultaneously POT as the main component of the luminescent layer and tris(2-phenylpyridine)iridium complex (hereinafter referred to as Ir(Ppy)₃) as a phosphorescent organic metal complex from different sources by the binary deposition method. The concentration of Ir(Ppy)₃ at this time was 7 wt %. Using the same vacuum deposition apparatus without breaking the vacuum, tris(8-hydroxyquinoline)aluminum (hereinafter referred to as Alq₃) was deposited to a film thickness of 50 nm on the luminescent layer 5 to form the electron transporting layer 7. On the electron transporting layer 7 were further deposited lithium fluoride (LiF) to a film thickness of 0.5 nm and aluminum to a film thickness of 170 nm to form the cathode 8 while maintaining the vacuum.

The organic EL element thus obtained was connected to an external source of electricity for application of DC voltage. This and other organic EL elements similarly prepared were confirmed to possess the luminous characteristics shown in Table 15. The maximum wavelength of the emission spectrum of the element was 512 nm and emission of light from Ir(Ppy)₃ was confirmed.

### Example 2

An organic EL element was prepared as in Example 1 with the exception of using 3,4-BPOT as the main component of the luminescent layer 5. The characteristics of this element are shown in Table 15.

### Example 3

An organic EL element was prepared as in Example 1 with the exception of using 3,5-BPOT as the main component of the luminescent layer 5. Emission of light from Ir(Ppy)₃ was confirmed for this organic EL element.

### Comparative Example 1

An organic EL element was prepared as in Example 1 with the exception of using 3-phenyl-4-(1′-naphthyl)-5-phenyl-1,2,4-triazole (hereinafter referred to as TAZ).

### Example 4

An organic EL element having the layered structure shown in FIG. 1 less the hole injecting layer 3 was prepared in the following manner.

As in Example 1, an ITO layer (anode 2) was provided on the substrate 1 and N,N′-dinaphthyl-N,N′-diphenyl-4,4′-diaminobiphenyl (hereinafter referred to as NPD) was deposited on the ITO layer to a film thickness of 40 nm to form the hole transporting layer 4. Using the same vacuum deposition apparatus without breaking the vacuum, the luminescent layer 5 was formed on the hole transporting layer 4 by depositing simultaneously 4,4′-N,N′-dicarbazoldiphenyl (hereinafter referred to as CBP) as the main component and Ir(Ppy)₃ as a phosphorescent organic metal complex from different sources to a film thickness of 20 nm by the binary deposition method. The concentration of Ir(Ppy)₃ at this time was 6 wt %. Using the same vacuum deposition apparatus without breaking the vacuum, POT was deposited on the luminescent layer 5 to a film thickness of 6 nm to form the hole blocking layer 6. On this layer was further deposited Alq₃ to a film thickness of 20 nm to form the electron transporting layer 7 while maintaining the vacuum. On the electron transporting layer 7 were further deposited LiF to a thickness of 0.6 nm and aluminum to a thickness of 150 nm to form the cathode 8 while maintaining the vacuum.

The organic EL element thus obtained was connected to an external source of electricity for application of DC voltage. This organic EL element was confirmed to possess the luminous characteristics shown in Table 15. The maximum wavelength of the emission spectrum of the element was 512 nm and emission of light from Ir(Ppy)₃ was confirmed.

### Example 5

An organic EL element was prepared as in Example 4 with the exception of using 3,4-BPOT as the hole blocking layer 6.

### Example 6

An organic EL element was prepared as in Example 4 with the exception of using 3,5-BPOT as the hole blocking layer 6.

### Comparative Example 2

An organic EL element was prepared as in Example 4 with the exception of using 2,9-dimethyl-4,7-diphenyl-1,10-phenanthroline (hereinafter referred to as BCP) as the hole blocking layer 6.

The characteristics of all the elements are shown together in Table 15.

TABLE 15

| | Voltage at | Maximum | Maximum |
|---|---|---|---|
| | initiation of | luminance | luminous |
| | luminescence | efficiency | efficiency |
| | (V) | (cd/A) | (lm/W) |
| Example 1 | 3.5 | 39.7 | 14.72 |
| Example 2 | 3.5 | 30.3 | 13.58 |
| Comparative | 4.0 | 27.0 | 11.07 |
| example 1 | | | |
| Example 4 | 3.5 | 35.4 | 18.72 |
| Example 5 | 3.5 | 33.8 | 17.11 |
| Example 6 | 3.0 | 40.1 | 19.32 |
| Comparative | 4.0 | 31.7 | 16.61 |
| example 2 | | | |

### Supplementary Example

The candidate compounds for the main component of the luminescent layer (host material) were tested for their heat-resistant characteristics by measuring the glass transition temperature (Tg) by DSC. It is to be noted that TAZ, CBP, BCP and OXD-7 are well-known host materials and OXD-7 stands for 1,3-bis[(4-t-butylphenyl)-1,3,4-oxadiazolyl]phenylene. The results are shown in Table 16.

TABLE 16

| | Glass transition |
|---|---|
| | temperature (Tg) |
| Host material | (° C.) |
| POT | 102 |
| 3,4-BPOT | 122 |
| 3,5-BPOT | 115 |
| TAZ | —¹⁾ |
| CBP | —¹⁾ |
| BCP | —¹⁾ |
| OXD-7 | —¹⁾ |

¹⁾Not observed due to high crystallinity

### INDUSTRIAL APPLICABILITY

An organic EL element prepared according to this invention is applicable to any one of single elements, elements arranged in array and elements in which the anode and the cathode are arranged in X-Y matrix. Through incorporation of a compound having a specified skeleton and a phosphorescent metal complex in its luminescent layer, the element achieves higher luminous efficiency and better driving stability than the conventional elements utilizing light emission from the singlet state and performs excellently in applications to full-color or multicolor panels.

1. An organic electroluminescent element comprising a substrate, an anode, an organic layer and a cathode placed in layer one upon another wherein at least one layer in the organic layer comprises an azole compound having an oxadiazole structure represented by the following formula I and a triazole structure represented by the following formula II in the same molecule: 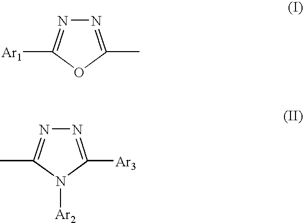
in the formulas, Ar₁—Ar₃ are independently substituted or unsubstituted aromatic hydrocarbon groups or aromatic heterocyclic groups, Ar₁ is a single bond when the structure represented by formula I is a divalent group and one or both of Ar₂ and Ar₃ are single bonds when the structure represented by formula II is a divalent or trivalent group.

2. An organic electroluminescent element as described in claim 1 wherein the azole compound is represented by any one of the following general formulas IV to VIII: 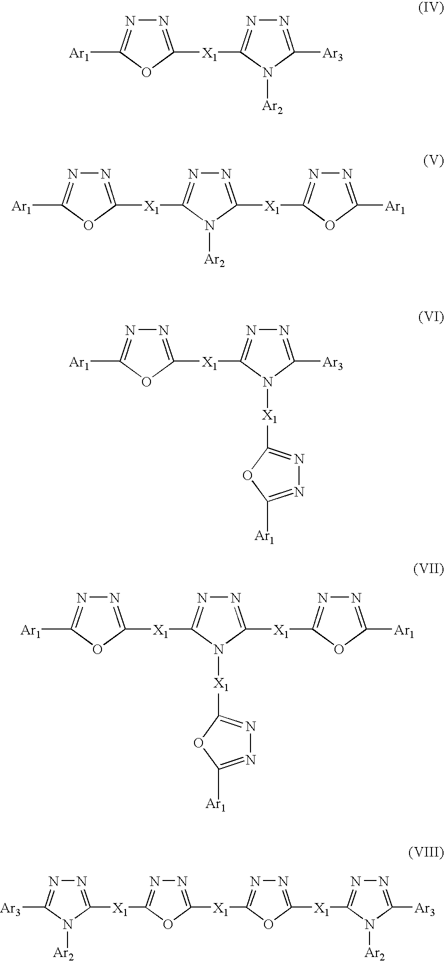
in the formulas, Ar₁—Ar₃ are independently substituted or unsubstituted aromatic hydrocarbon groups or aromatic heterocyclic groups and X₁ is a divalent aromatic hydrocarbon group.

3. An organic electroluminescent element as described in claim 1 wherein at least one layer in the organic layer is a luminescent layer containing a host agent and a doping agent and an azole compound having the oxadiazole structure represented by formula I and the triazole structure represented by formula II in the same molecule is used as said host agent.

4. An organic electroluminescent element as described in claim 3 wherein the doping agent contains at least one compound selected from phosphorescent ortho-metalated metal complexes and porphyrin metal complexes.

5. An organic electroluminescent element as described in claim 4 wherein the central metal of the metal complexes is at least one metal selected from ruthenium, rhodium, palladium, silver, rhenium, osmium, iridium, platinum and gold.

6. An organic electroluminescent element as described in claim 1 wherein a hole blocking layer is provided between the luminescent layer and the cathode.

7. An organic electroluminescent element as described in claim 1 wherein an electron transporting layer is provided between the luminescent layer and the cathode.

8. An organic electroluminescent element as described in claim 1 wherein the layer in which the azole compound is incorporated is the hole blocking layer or the electron transporting layer.
